(19) United States
(12) Patent Application Publication
(10) Pub. No.: US 2024/0370041 A1
(43) Pub. Date: Nov. 7, 2024

(54) SUBSTRATE PROCESSING APPARATUS AND SUBSTRATE PROCESSING METHOD

(71) Applicant: TES CO., LTD, Yongin-si (KR)

(72) Inventors: Shin-Myoung KIM, Yongin-si (KR); Il KIM, Yongin-si (KR); Jae-Hoon LEE, Yongin-si (KR)

(73) Assignee: TES CO., LTD, Yongin-si (KR)

(21) Appl. No.: 18/641,406

(22) Filed: Apr. 21, 2024

(30) Foreign Application Priority Data
May 2, 2023 (KR) 10-2023-0056890

(51) Int. Cl. G05D 7/06

(52) U.S. Cl. CPC G05D 7/0617

(57) ABSTRACT

Provided is a substrate processing apparatus and a substrate processing method, more particularly, a substrate processing apparatus and a substrate processing method that reduce attachment of foreign substances such as particles to a substrate when the substrate is inserted into a process chamber of the substrate processing apparatus or is drawn out of the process chamber.

### CROSS-REFERENCE TO RELATED APPLICATION

This application is based on and claims priority under 35 U.S.C. § 119 to Korean Patent Application No. 10-2023-0056890, filed on May 2, 2023, in the Korean Intellectual Property Office, the disclosure of which is incorporated by reference herein in its entirety.

### TECHNICAL FIELD

The present disclosure relates to a substrate processing apparatus and a substrate processing method, and more particularly, a substrate processing apparatus and a substrate processing method that reduce attachment of foreign substances such as particles to a substrate when the substrate is inserted into a process chamber of the substrate processing apparatus or is drawn out of the process chamber.

### BACKGROUND

In general, a substrate processing apparatus may include a process chamber that performs various processing processes on a substrate, and a transfer chamber connected to the process chamber to supply unprocessed substrates to the process chamber and draw processed substrates out of the process chamber. The above-described process chamber and transfer chamber may be connected to each other by a gate valve including a gate.

However, in the above-described structure, when the gate moves to open or close, foreign substances such as particles attached around the gate or around an opening of the process chamber may be introduced into the inside of the process chamber through the opening.

As such, particles introduced into the process chamber may be attached to an upper surface of the substrate and contaminate the substrate or cause damage to the substrate.

### SUMMARY

To overcome the above problem, an object of the present disclosure is to provide a substrate processing apparatus for reducing attachment of foreign substances such as particles to a substrate when the substrate is inserted into a process chamber of the substrate processing apparatus or is drawn out of the process chamber.

According to an aspect of the present disclosure, a substrate processing method includes opening a gate connecting a transfer chamber and a process chamber, supplying a purge gas into the process chamber through a shower head of the process chamber, inserting a substrate into the process chamber and placing the substrate on a heater inside the process chamber, closing the gate and stopping the supplying of the purge gas, supplying the process gas through the shower head, and raising the heater and performing a process on the substrate

The substrate processing method may further include, after the performing of the process on the substrate, lowering the heater and stopping the supplying of the process gas, opening the gate, supplying the purge gas into the process chamber through the shower head inside the process chamber, drawing the substrate, on which the process is completed, out of the process chamber, inserting an unprocessed substrate into the process chamber, and placing the substrate on the heater, and closing the gate and stopping the supplying of the purge gas.

The purge gas may start being supplied through the shower head at a time at which the gate is open, and the purge gas may stop being supplied through shower head at a time at which the gate is closed.

The purge gas may start being supplied through the shower head at a first time prior to the opening of the gate.

The purge gas may stop being supplied through the shower head at a second time after the opening of the gate.

The purge gas may be supplied through the shower head at a time at which the heater is lowered or at a third time prior to lowering of the heater.

When the purge gas is supplied, a pressure inside the process chamber may be maintained below a pressure of the transfer chamber.

According to another aspect of the present disclosure, a substrate processing apparatus includes at least one process chamber connected to a transfer chamber transferring a substrate and providing a processing space for the substrate, a shower head provided at an upper portion of the processing space and supplying a process gas or a purge gas toward the substrate, a heater that is provided at a lower portion of the processing space to be raised or lowered and on which the substrate is placed, an exhaust port connected to the lower portion of the process chamber and exhausting gas inside the chamber to generate a downward airflow inside process chamber, and a gate located between the transfer chamber and the process chamber, wherein the purge gas is supplied through the shower head according to an opening and closing operation of the gate.

The purge gas may start being supplied through the shower head at a time at which the gate is open, and the purge gas may stop being supplied through shower head at a time at which the gate is closed.

The purge gas may start being supplied through the shower head at a first time prior to the opening of the gate.

the purge gas may stop being supplied through the shower head at a second time after the opening of the gate.

The purge gas may start being supplied through the shower head at a time at which the heater is lowered or at a third time prior to the lowering of the heater.

The purge gas may be supplied or stopped through the shower head according to a process schedule for the substrate, or a sensor configured to detect opening and closing of the gate may be provided, and the purge gas may be supplied and stopped through the shower head according to a gate opening and closing signal of the sensor.

### BRIEF DESCRIPTION OF THE DRAWINGS

Embodiments will be more clearly understood from the following detailed description taken in conjunction with the accompanying drawings in which:

FIG. 1 is a plan view showing a substrate processing apparatus according to an embodiment of the present disclosure;

FIG. 2 is a side cross-sectional view showing one process chamber connected to a transfer chamber;

FIG. 3 is a graph showing opening and closing of a gate during a process for a substrate in a process chamber, whether a process gas and a purge gas are supplied through a shower head, and a raising and lowering operation of a heater;

FIGS. 4 to 6 are graphs showing a process sequence according to other embodiments; and

FIG. 7 is a schematic side cross-sectional view of a flow of gas inside a process chamber 200 when a purge gas is supplied through a shower head according to opening and closing of a gate.

### DETAILED DESCRIPTION OF THE EMBODIMENTS

Hereinafter, a substrate processing apparatus according to an embodiment of the present disclosure will be described in detail with reference to the drawings.

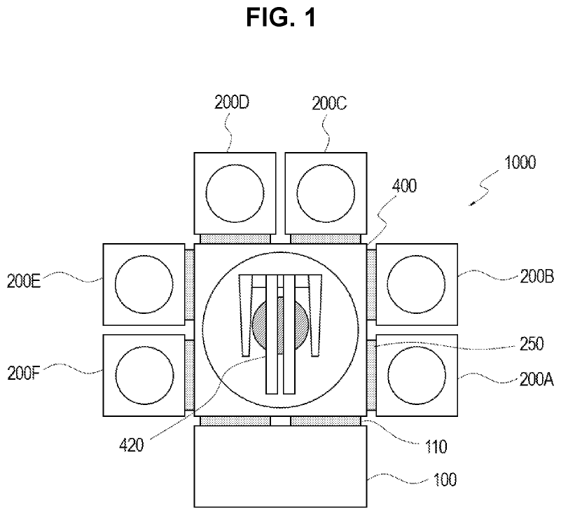

FIG. 1 is a plan view showing a substrate processing apparatus 1000 according to an embodiment of the present disclosure.

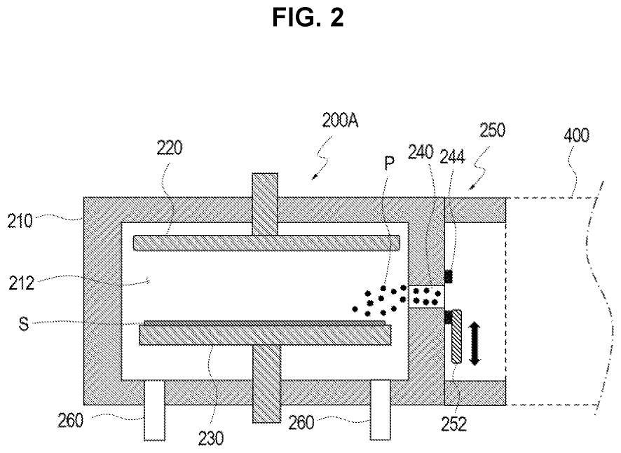

Referring to FIG. 1, the substrate processing apparatus 1000 may include at least one process chambers 200A to 200F that provides a processing space 212 (refer to FIG. 2) for the substrate S (refer to FIG. 2) and is used to perform a processing process for the substrate S, and a transfer chamber 400 connected to the process chambers 200A to 200F to transfer the substrate S. One side of the transfer chamber 400 may be connected to a load lock chamber 100.

The transfer chamber 400 and the process chambers 200A to 200F may be connected to each other by a first gate valve 250, and similarly, the transfer chamber 400 and the load lock chamber 100 may also be connected to each other by a second gate valve 110.

A transfer arm unit 420 for transferring the substrate S may be provided in the transfer chamber 400. Thus, the substrate S that is not processed may be transferred to the transfer chamber 400 through the load lock chamber 100 and transferred to the process chambers 200A to 200F by the transfer arm unit 420.

The substrate S that is processed in the process chambers 200A to 200F may be extended by the transfer arm unit 420 of the transfer chamber 400 and drawn out the process chambers 200A to 200F through the load lock chamber 100.

When the substrate S is inserted into the process chambers 200A to 200F from the transfer chamber 400, or when the substrate S is drawn out of the process chambers 200A to 200F into the transfer chamber 400, a gate 252 (refer to FIG. 2) of the first gate valve 250 may be open.

FIG. 2 is a side cross-sectional view showing one process chamber 200A connected to the transfer chamber 400.

Referring to FIG. 2, the process chamber 200A may include a chamber body 210 in which a processing space 212 for the substrate S is provided. In the drawing, the chamber body 210 is shown as a single component, but it is not limited thereto, and the chamber body is provided with an open top, and a chamber lead (not shown) that is detachable from the open top of the chamber body may also be provided.

A shower head 220 may be provided inside the chamber body 210 to supply a process gas or a purge gas toward the substrate S.

The shower head 220 may be provided at an upper portion of the processing space 212 and may supply a process gas or a purge gas toward the substrate S at a lower portion.

A heater 230 on which the substrate S is placed may be provided in the processing space 212. The heater 230 may heat and support the substrate S. The heater 230 may be raised and lowered, and thus may be lowered when the substrate S is inserted into and out of the process chamber 200A and may be raised to a processing position when the substrate S is processed.

An exhaust port 260 may be provided at a lower portion of the chamber body 210 to exhaust internal gas of the chamber body 210. The exhaust port 260 may be connected to an exhaust pump (not shown) to exhaust gas inside the chamber body 210 and generate a downward airflow inside the chamber body 210.

As described above, one side of the chamber body 210 may be connected to the transfer chamber 400 through the first gate valve 250.

In this case, the opening 240 through which the substrate S is inserted into and out of the process chamber 200A may be formed in one side of the chamber body 210, that is, a side wall connected to the first gate valve 250.

The gate 252 that opens and closes the opening 240 may be provided inside the first gate valve 250. The gate 252 may be located between the transfer chamber 400 and the process chamber 200A. The gate 252 may open and close the opening 240 by moving up and down, for example. In this case, a sealing member 244 may be located at an edge of the opening 240.

The raising and lowering operation of the heater 230, gas supply through the shower head 220, and the operation of the gate 252 may be controlled through a controller (not shown).

In the above-described structure, when the gate 252 moves to open and close the opening 240, foreign substances P such as particles around the opening 240 or attached to the sealing member 244 may be introduced into the chamber body 210 through the opening 240.

The opening 240 has a smaller cross-sectional area than the chamber body 210 or the first gate valve 250, and thus when the opening 240 is open or closed, the foreign substances P may be introduced into the process chamber 200A according to the Venturi effect.

In particular, when the pressure inside the process chamber 200A is lower than that of the transfer chamber 400, the Venturi effect described above may increase, and thus the foreign substances P may be easily introduced into the process chamber 200A.

The foreign substances P introduced into the process chamber 200A may attach to the substrate S and cause damage or contamination of the substrate S.

When the gate 252 is open and closed, this corresponds to the case in which the substrate S is inserted into and out of the process chamber 200A, and thus the heater 230 may be provided in a lowered state. In this case, the height of an upper surface of the heater 230 may be lower than that of the opening 240. Therefore, the foreign substances P introduced through the opening 240 may be easily attached to the substrate S above the heater 230.

In the present disclosure, to resolve the above-described problem, a purge gas may be supplied through the shower head 220 according to the opening and closing operation of the gate 252.

That is, the controller may supply a purge gas such as N₂ or Ar through the shower head 220 when the gate 252 is open or closed. In this case, the exhaust port 260 described above may continue to operate. Accordingly, the purge gas supplied through the shower head 220 may move to the lower portion of the processing space 212 by downward airflow by the exhaust port 260 and be discharged through the exhaust port 260. In this case, the foreign substances P, such as particles introduced into the processing space 212, may also move downward due to the downward airflow of the purge gas and be discharged through the exhaust port 260. Hereinafter, this will be described in detail.

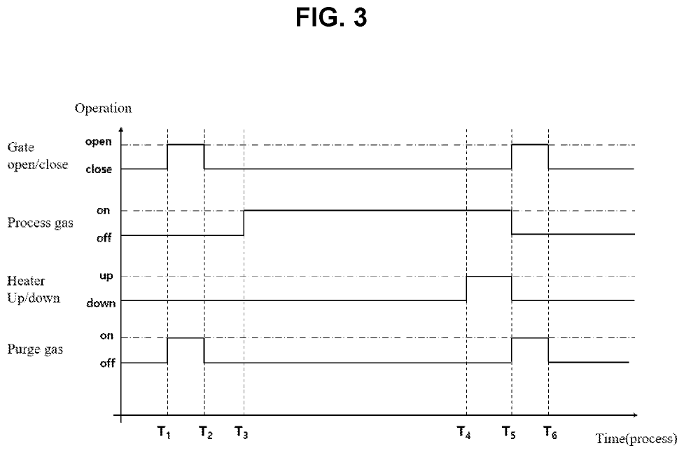

FIG. 3 is a graph showing opening and closing of the gate 252 described above during the process for the substrate S in the process chamber 200A, whether a process gas and a purge gas are supplied through the shower head 220, and the raising and lowering operation of the heater 230. In FIG. 3, a horizontal axis shows time according to the process, and a vertical axis shows the opening and closing of the gate 252 from the top, whether the process gas is supplied through the shower head 220, the raising and lowering operation of the heater 230, and whether the purge gas is supplied through the shower head 220.

Referring to FIG. 3, the controller may start supplying the purge gas through the shower head 220 when the gate 252 is open (T₁) and stop supplying the purge gas through the shower head 220 when the gate 252 is closed (T₂).

The controller may first open the gate 252 and then may supply the purge gas through the shower head 220 inside the process chamber 200A.

In this case, the purge gas may be supplied simultaneously through the shower head 220 at the time T₁ when the gate 252 is open for the process for the substrate S.

When the gate 252 is open, the heater 230 is maintained in a lowered state, and the substrate S inserted into the process chamber 200A through the opening 240 is placed on the upper surface of the heater 230.

Then, the gate 252 may be closed (T₂), and the supply of purge gas through the shower head 220 may also be stopped when the gate 252 is closed.

After closing the gate 252, the process gas is supplied to the substrate S through the shower head 220 (T₃).

After supply of the process gas, if an environment inside the chamber body 210 satisfies process conditions for the substrate S, the heater 230 rises to the process height (T₄). Then, the process for the substrate S proceeds.

When the process for the substrate S is completed, the supply of the process gas through the shower head 220 is stopped, and the heater 230 is lowered (T₅). At this point (T₅), the gate 252 may be open, and the purge gas may be supplied again through the shower head 220 at the same time.

When the gate 252 is open, the substrate S on which the process is completed may be drawn out of the process chamber 200A through the opening 240, and the substrate on which the process is not performed may be inserted into the process chamber 200A through the opening 240 and placed on the heater 230. Then, the gate 252 is closed (T₆), and the supply of the purge gas through the shower head 220 may also be stopped when the gate 252 is closed. When an unprocessed substrate is placed on the heater 230, the above-described operations, that is, supplying process gas through the shower head 220, and subsequent operations may be repeatedly performed.

During the above-described process, the exhaust port 260 may be continuously driven.

Therefore, according to the present embodiment, a purge gas may be supplied through the shower head 220 according to the opening and closing of the gate 252, and a strong downward airflow may be generated inside the chamber body 210 by the exhaust port 260. In particular, according to the present disclosure, even when the purge gas is supplied as described above, the pressure inside the process chamber 200A may be maintained below the pressure of the transfer chamber 400. Accordingly, the foreign substances P introduced through the opening 240 may be prevented from being attached to the substrate S and discharged through the exhaust port 260.

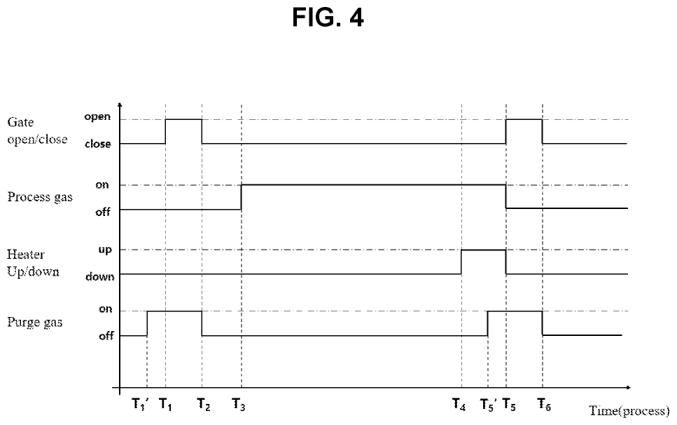

FIG. 4 is a graph showing a process sequence according to another embodiment.

Referring to FIG. 4, according to the present embodiment, the controller may supply the purge gas through the shower head 220 at a first time (T₁′ to T₁ and T₅′ to T₅) prior to opening the gate 252.

In other words, the purge gas may be supplied through the shower head 220 at a time T₁′ prior to the time T₁ at which the gate 252 is open for the process for the substrate S.

When the process for the substrate S is completed, the supply of the process gas through the shower head 220 is stopped, and the heater 230 is lowered (T₅). At this point T₅, the gate 252 is open. In this case, the purge gas may be supplied through the shower head 220 at the time T₅′ prior to the gate 252 is open (T₅) or at the time T₅′ prior to the lowering time T₅ of the heater 230.

Here, in FIG. 4, the time T₅′ prior to the lowering time T₅ of the heater 230 is shown to be the same as the time T₅′ prior to the time T₅ at which the gate 252 is open but may be implemented as different times. That is, the controller may supply a purge gas through the shower head 220 at a third time prior to the heater 230 is lowered, and in this case, the third time may be determined to be the same time as the above-described second time or may be determined as a different time.

In the embodiment of FIG. 4, the supply of the purge gas through the shower head 220 may be stopped at the times T₂ and T₆ at which the gate 252 is closed.

As a result, a downward airflow may be generated by previously supplying the purge gas through the shower head 220 before the gate 252 is open, and even when the foreign substances P are introduced along with opening of the gate 252, the foreign substances P may be effectively discharged through the exhaust port 260.

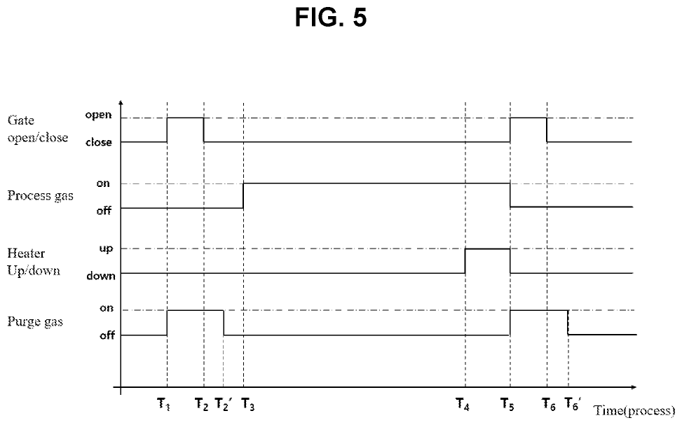

FIG. 5 is a graph showing a process sequence according to another embodiment.

Referring to FIG. 5, according to the present embodiment, the controller may stop supply of the purge gas through the shower head 220 at the second times (T₂ to T₂′ and T₆ to T₆′) after closing of the gate 252.

That is, for the process of the substrate S, the gate 252 may be open to insert the substrate S into the process chamber and the gate 252 may be closed (T₂). In this case, the supply of the purge gas through the shower head 220 may not be stopped immediately, but the purge gas may continue to be supplied for a predetermined time and then stopped (T₂′).

When the process for the substrate S is completed, the supply of the process gas through the shower head 220 may be stopped, and the heater 230 may be lowered (T₅). At this point (T₅), the gate 252 is open.

When the gate 252 is open, the substrate S may be drawn out of the process chamber through the opening 240, and an unprocessed substrate may be inserted into the process chamber. Then, the gate 252 is closed (T₆). In this case, the supply of the purge gas through the shower head 220 may not be stopped immediately, but the purge gas may continue to be supplied for a predetermined time and then stopped (T₆′).

According to the embodiment of FIG. 5, the supply of the purge gas through the shower head 220 may begin at the times T₁ and T₅ at which the gate 252 is open.

As a result, the gate 252 may be closed and the supply of the purge gas through the shower head 220 may not be immediately stopped, but the purge gas may be supplied for a predetermined time to maintain a downward airflow, and thus the foreign substances P remaining inside the chamber body 210 may be discharged through the exhaust port 260.

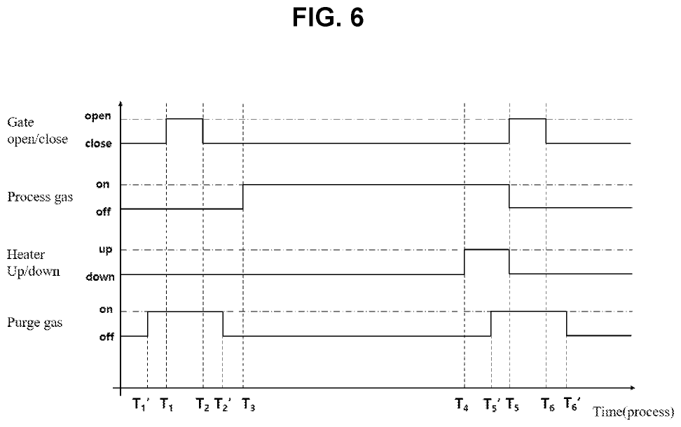

FIG. 6 is a graph showing a process sequence according to another embodiment.

Referring to FIG. 6, according to the present embodiment, the controller may supply the purge gas through the shower head 220 at the first time (T₁′ to T₁ and T₅′ to T₅) prior to opening the gate 252 and may close the gate 252 and stop the supply of the purge gas through the shower head 220 at the second time (T₂ to T₂′ and T₆ to T₆′) after the closing of the gate 252.

In other words, the present embodiment corresponds to the case in which the embodiments of FIGS. 3 and 4 described above are combined.

For example, the purge gas may be supplied through the shower head 220 at a time T₁′ prior to the time T₁ at which the gate 252 is open for the process for the substrate S.

When the substrate S is inserted into the process chamber and the gate 252 is closed (T₂), the supply of the purge gas through the shower head 220 may not be stopped immediately, but the purge gas may continue to be supplied for a predetermined time and then stopped (T₂′).

When the process for the substrate S is completed, the supply of the process gas through the shower head 220 may be stopped, and the heater 230 may be lowered (T₅). At this point (T₅), the gate 252 is open. In this case, the purge gas may be supplied through the shower head 220 at the time T₅′ prior to the gate 252 is open (T₅) or at the time T₅′ prior to the lowering time T₅ of the heater 230.

When the gate 252 is open, the substrate S may be drawn out of the process chamber through the opening 240, and an unprocessed substrate may be inserted into the process chamber. Then, the gate 252 is closed (T₆). In this case, the supply of the purge gas through the shower head 220 may not be stopped immediately, but the purge gas may continue to be supplied for a predetermined time and then stopped (T₆′).

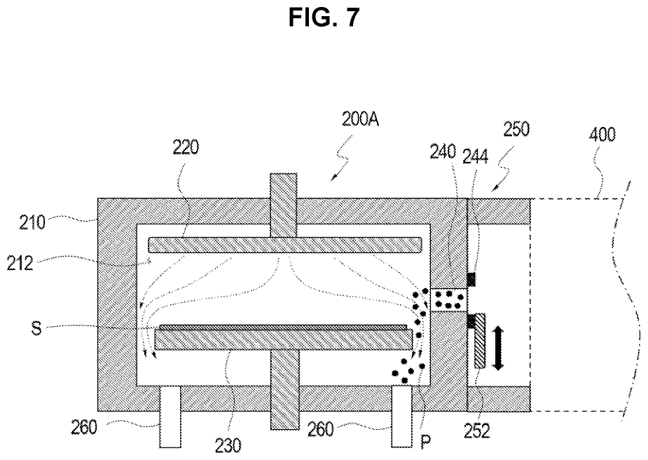

FIG. 7 is a schematic side cross-sectional view of a flow of gas inside the process chamber 200A when a purge gas is supplied through the shower head 220 according to opening and closing of the gate 252 according to the embodiments of FIGS. 3 to 6 described above. In FIG. 7, for convenience of explanation, the gate 252 is shown open and the substrate S is shown to be placed on the heater 230 of the process chamber 200A.

Referring to FIG. 7, the purge gas supplied through the shower head 220 forms a strong downward airflow toward a lower portion of the processing space 212, as indicated by a hidden line. This is because the gas in the processing space 212 is exhausted through the exhaust port 260 connected to the lower portion of the process chamber 200A.

Therefore, even if the foreign substances P, such as particles attached to the gate 252 and the sealing member 244, are introduced into the inside of the process chamber 200A through the opening 240, the foreign substances P may not approach the substrate S, may descend toward the bottom due to the downward airflow of the purge gas and may be exhausted through the exhaust port 260.

As a result of the present inventor performing a test with a substrate with a diameter of 300 mm, when a substrate processing apparatus according to the related art is used, about 2.08 particles are attached to each substrate, and in contrast, when the substrate processing apparatus according to the present disclosure is used, only about 0.75 particles are attached to each substrate, and it may be seen that the number of attached particles may be reduced by more than 64%.

In the substrate processing apparatus 1000, the controller may perform the supply and interruption of the purge gas through the shower head 220 according to a process schedule or may actively perform the supply and interruption of the purge gas according to a detection value of a sensor.

For example, the controller may supply and stop the purge gas through the shower head 220 according to a process schedule (or recipe) for the substrate S. In this case, when the process for the substrate S is determined, the purge gas may be supplied and stopped at a predetermined time according to the recipe of the determined process.

The substrate processing apparatus 1000 may include a sensor (not shown) that detects opening and closing of the gate 252. When the gate 252 is open or closed, the sensor may transmit a gate opening and closing signal to the controller. In this case, the controller may determine supply and interruption of the purge gas through the shower head 220 according to a gate opening and closing signal of the sensor.

According to the present disclosure having the above-described configuration, when the gate between the transfer chamber and the process chamber may be open and closed to draw the substrate into or out of the process chamber of the substrate processing apparatus, a strong downward airflow may be formed by supplying the purge gas through the shower head inside the process chamber.

In this case, even if foreign substances such as particles are introduced into the inside of the process chamber, the particles may not be attached to the substrate due to the above-described downward airflow and may be discharged to the outside of the process chamber through the exhaust port.

Although the present disclosure has been described above with reference to exemplary embodiments, those skilled in the art may modify and change the present disclosure in various ways without departing from the spirit and scope of the present disclosure as set forth in the claims described below. Therefore, when the modified implementation basically includes the elements of the claims of the present disclosure, it should be considered to be included in the technical scope of the present disclosure.

What is claimed is:

1. A substrate processing method comprising:
opening a gate connecting a transfer chamber and a process chamber;
supplying a purge gas into the process chamber through a shower head of the process chamber;
inserting a substrate into the process chamber and placing the substrate on a heater inside the process chamber;
closing the gate and stopping the supplying of the purge gas;
supplying the process gas into the process chamber through the shower head; and
raising the heater and performing a process on the substrate.

2. The substrate processing method of claim 1, further comprising: after the performing of the process on the substrate,
lowering the heater and stopping the supplying of the process gas;
opening the gate;
supplying the purge gas into the process chamber through the shower head of the process chamber;
drawing the substrate, on which the process is completed, out of the process chamber, inserting an unprocessed substrate into the process chamber, and placing the substrate on the heater; and
closing the gate and stopping the supplying of the purge gas.

3. The substrate processing method of claim 1, wherein the purge gas starts being supplied through the shower head at a time at which the gate is open, and the purge gas stops being supplied through shower head at a time at which the gate is closed.

4. The substrate processing method of claim 1, wherein the purge gas starts being supplied through the shower head at a first time prior to the opening of the gate.

5. The substrate processing method of claim 1, wherein the purge gas stops being supplied through the shower head at a second time after the opening of the gate.

6. The substrate processing method of claim 1, wherein the purge gas starts being supplied through the shower head at a time at which the heater is lowered or at a third time prior to lowering of the heater.

7. The substrate processing method of claim 1, wherein, when the purge gas is supplied, a pressure inside the process chamber is maintained below a pressure of the transfer chamber.

8. The substrate processing method of claim 2, wherein the purge gas starts being supplied through the shower head at a time at which the gate is open, and the purge gas stops being supplied through shower head at a time at which the gate is closed.

9. The substrate processing method of claim 2, wherein the purge gas starts being supplied through the shower head at a first time prior to the opening of the gate.

10. The substrate processing method of claim 2, wherein the purge gas stops being supplied through the shower head at a second time after the opening of the gate.

11. The substrate processing method of claim 2, wherein the purge gas starts being supplied through the shower head at a time at which the heater is lowered or at a third time prior to lowering of the heater.

12. The substrate processing method of claim 2, wherein, when the purge gas is supplied, a pressure inside the process chamber is maintained below a pressure of the transfer chamber.

13. A substrate processing apparatus comprising:
at least one process chamber connected to a transfer chamber transferring a substrate and providing a processing space for the substrate;
a shower head provided at an upper portion of the processing space and supplying a process gas or a purge gas to the substrate;
a heater that is provided at a lower portion of the processing space to be raised or lowered and on which the substrate is placed;
an exhaust port connected to the lower portion of the process chamber and exhausting gas inside the chamber to generate a downward airflow inside process chamber; and
a gate located between the transfer chamber and the process chamber,
wherein the purge gas is supplied through the shower head according to an opening and closing of the gate.

14. The substrate processing apparatus of claim 13, wherein the purge gas starts being supplied through the shower head at a time at which the gate is open, and the purge gas stops being supplied through shower head at a time at which the gate is closed.

15. The substrate processing apparatus of claim 13, wherein the purge gas starts being supplied through the shower head at a first time prior to the opening of the gate.

16. The substrate processing apparatus of claim 13, wherein the purge gas stops being supplied through the shower head at a second time after the opening of the gate.

17. The substrate processing apparatus of claim 13, wherein the purge gas starts being supplied through the shower head at a time at which the heater is lowered or at a third time prior to lowering of the heater.

18. The substrate processing apparatus of claim 13, wherein the purge gas is supplied or stopped through the shower head according to a process schedule for the substrate, or
a sensor configured to detect opening and closing of the gate is provided, and the purge gas is supplied and stopped through the shower head according to a gate opening and closing signal of the sensor.
